(19) United States
(12) Patent Application Publication
(10) Pub. No.: US 2025/0157689 A1
(43) Pub. Date: May 15, 2025

(54) GRID PATTERN INTERCONNECT METHOD FOR ELECTRICAL CIRCUITS AND SPLICING DEVICE FOR SAME

(71) Applicant: Aptiv Technologies AG, Schaffhausen (CH)

(72) Inventors: David SIEGFRIED, Warren, OH (US); Joseph Sudik, JR., Niles, OH (US); David R. Peterson, Aurora, OH (US)

(21) Appl. No.: 18/899,878

(22) Filed: Sep. 27, 2024

Related U.S. Application Data
(60) Provisional application No. 63/598,675, filed on Nov. 14, 2023.

(51) Int. Cl. H01B 5/14; H01B 3/42; H01B 13/00; H05K 1/18

(52) U.S. Cl. CPC H01B 5/14; H01B 3/42; H01B 13/003; H01B 13/0036; H05K 1/189

(57) ABSTRACT

A method is disclosed for interconnecting electrical conductors using a grid pattern formed from an electrically conductive material on a dielectric substrate. The grid pattern includes regularly spaced apertures forming an interconnected grid array of conductive traces. By severing connections between a separate conductive trace and the rest of the grid array, individual conductive traces are created. A first conductor from a first electrical cable is attached to a first contact pad defined by one of the separate conductive traces, and a second conductor from a second electrical cable is attached to a second contact pad defined by another separate conductive trace. This arrangement enables the interconnection of the first conductor to the second conductor via the separate conductive trace.

### CROSS-REFERENCE TO RELATED APPLICATIONS

This application claims the benefit of and priority to U.S. provisional application 63/598,675, titled “Method of Interconnecting Flat Electrical Cables”, filed Nov. 14, 2023, the contents of which are incorporated by reference herein.

### TECHNICAL FIELD

This disclosure is directed to a method of interconnecting flat electrical cables, such as flat flexible cables and/or flexible printed circuits.

### BACKGROUND

Previous methods for creating electrical connections between conductors have involved various techniques such as soldering, welding, or crimping. These traditional methods typically require manual labor and are time-consuming, leading to increased manufacturing costs and potential inconsistencies in the quality of the connections. Additionally, these methods may not be suitable for creating intricate or complex electrical interconnections, especially in cases where a high degree of precision is required.

In some instances, printed circuit boards (PCBs) have been used to facilitate electrical connections between components. PCBs are typically manufactured by etching conductive traces onto a non-conductive substrate, allowing for the routing of electrical signals between different components. While PCBs offer advantages in terms of scalability and repeatability, they may not be well-suited for applications requiring flexible or conformal interconnections due to their rigid nature.

Furthermore, techniques involving wire bonding or ribbon bonding have been utilized to establish electrical connections in electronic devices. These methods involve bonding fine wires or ribbons between components to create electrical pathways. While wire bonding and ribbon bonding can provide reliable connections in certain applications, they may be limited in terms of the complexity of interconnections that can be achieved and may not be suitable for high-density interconnect applications. However, none of these approaches have provided a comprehensive solution that combines the features described in this disclosure.

### SUMMARY

In some aspects, the techniques described herein relate to a method, including: forming a grid pattern from a planar sheet of electrically conductive material defining a plurality of regularly spaced apertures therein that forms an interconnected grid array of conductive traces; attaching the interconnected grid array of conductive traces to a first dielectric substrate; forming a separate conductive trace from the interconnected grid array of conductive traces by severing connections between the separate conductor and the rest of the interconnected grid array of conductive traces; and attaching a first conductor in a first electrical cable to a first contact pad defined by the separate conductive trace and attaching a second conductor in a second electrical cable to a second contact pad defined by the separate conductive trace, thereby interconnecting the first conductor to the second conductor via the separate conductive trace.

In some aspects, the techniques described herein relate to a splicing device configured to interconnect flat flexible cables (FFC) and/or flexible printed circuits (FPC), the splicing device including: a grid pattern formed from a planar sheet of electrically conductive material having a plurality of regularly spaced apertures therein that forms an interconnected array grid of conductive traces; and a dielectric substrate attached to the interconnected grid array of conductive traces, a separate conductive trace being created from the interconnected grid array of conductive traces by severing connections between the separate conductor and the rest of the interconnected grid array of conductive traces.

### BRIEF DESCRIPTION OF THE DRAWINGS

FIG. 1 shows an isometric view of a splicing device configured to interconnect two or more flat electrical cables according to some embodiments;

FIG. 2 shows a cross section view of the splicing device of FIG. 1 according to some embodiments.

FIG. 3 shows an isometric view of the splicing device of FIG. 1 with portions of a substrate removed to expose an internal conductive grid pattern according to some embodiments.

FIG. 4 shows an isometric view of the splicing device of FIG. 1 with flat electrical cables attached to the internal conductive grid pattern according to some embodiments.

FIG. 5 shows an isometric view of the splicing device of FIG. 1 with the grid pattern severed to form separate conductors according to some embodiments.

FIG. 6 shows an exploded view of a splicing device configured to interconnect two or more flat electrical cables having two overlapping internal conductive grid patterns, each with a different grid pitch according to some embodiments.

FIG. 7 shows a cross section view of the splicing device of FIG. 6 according to some embodiments.

FIG. 8 shows a top isometric view of the splicing device of FIG. 6 with a substrate removed to expose the top grid pattern according to some embodiments.

FIG. 9 shows a bottom isometric view of the splicing device of FIG. 6 with a substrate removed to expose the bottom grid pattern according to some embodiments.

FIG. 10 shows an exploded view of a splicing device configured to interconnect two or more flat electrical cables having two overlapping internal conductive grid patterns, each with a distinct size according to some embodiments.

FIG. 11 shows a top isometric view of the splicing device of FIG. 10 with substrates removed to expose the grid patterns according to some embodiments.

FIG. 12 shows an exploded view of a splicing device configured to interconnect two or more flat electrical cables having two adjacent internal conductive grid patterns, each with a different grid pitch according to some embodiments.

FIG. 13 shows an isometric view of the splicing device of FIG. 12 with a substrate removed to expose the grid patterns according to some embodiments.

FIG. 14 shows a top view of a splicing device with the grid pattern severed to form separate conductors according to some embodiments.

FIG. 15 shows a top view of the splicing device of FIG. 14 with flat electrical cables attached to the internal conductive grid pattern according to some embodiments.

FIG. 16 shows an isometric view of a punch die configured to sever the grid pattern to form separate conductors according to some embodiments.

FIG. 17 shows a top view of the punch die of FIG. 16 according to some embodiments.

FIG. 18 shows an isometric view of a grid pattern of a splicing device severed by the punch die of FIG. 16 according to some embodiments.

FIG. 19 shows a top view of the grid pattern of FIG. 18 according to some embodiments.

FIG. 20 shows a flowchart of a method of interconnecting flat electrical cables according to some embodiments.

### DETAILED DESCRIPTION

A method of interconnecting flat flexible cables (FFC) and/or flexible printed circuits (FPC) using a splicing device having dielectric substrate with a single or double-sided conductor grid pattern attached thereto is presented herein. As used herein, an FFC is a flat flexible ribbon electrical cable having two or more electrical conductors with contacts on both ends. Further, as used herein, an FPC is a flat flexible printed circuit board in the form of a cable having two or more electrical conductors with contacts at both ends and additional electrical components, such as resistors, capacitors, diodes, connected to the conductors.

The method includes forming a grid pattern from a planar sheet of electrically conductive material, such as copper or a copper alloy, having a plurality of regularly spaced apertures therein that forms an interconnected array grid of conductive traces, e.g., a 4×4 grid, an 8×8 grid, or a 10×4 grid, etc. These conductive traces may have a width of 1.54 mm, 2.5 mm, or 4.08 mm. Alternatively, other conductive trace widths may be employed. The conductive traces may have a thickness in the range of 34.8 to 104.8 μm and may have a variety of conductor finishes (e.g., tin, silver, and/or gold plating). Alternatively, other conductive trace thicknesses may be employed.

The method also includes attaching at least one dielectric substrate to the bottom and/or top of the grid pattern. The substrate may be formed of polyethylene naphthalate (PEN), polyethylene terephthalate (PET), polyimide (PI), or other dielectric and substantially rigid materials. The substrate may be attached to the grid pattern by a laser welding process or a dielectric adhesive, such as an epoxy, silicone, or cyanoacrylate adhesive.

The method further includes forming one or more separate and disconnected conductive traces from the grid pattern that are configured for connecting one or more conductors of a first FFC or FPC to one or more conductors of a second FFC or FPC. Each of the separate conductors are formed by severing connections between the separate conductor and the rest of the grid, thereby creating a separate conductor that extends from a first connection pad configured to interconnect with a conductor in the first FFC or FPC to a second connection pad configured to interconnect with a conductor in the second FFC or FPC. The separate conductors may be severed from the grid pattern by punching out cross connections between the separate conductors and the rest of the grid pattern using a programmable punching mechanism as shown in FIG. 16. The separate conductors may alternatively be severed from the grid pattern by programmable laser cutting, water jet cutting, blanking, or blade cutting. These methods of forming the separate conductors has reduced processing cycle time, cost, and environmental impact issues compared to a chemical etching process that may be used to form separate conductors from a grid pattern. This is because a solid conductor sheet is stamped to produce a grid pattern which is then bonded to a substrate layer. The excess and scrap stamped material is easily recycled, not dissolved in chemical etching material that requires recovery as occurs with chemically etching a printed circuit board. Further, the grid pattern tooling and processes may be used for a variety of splicing devices/shapes rather than requiring dedicated tooling and processes for different grid configurations.

More than one separate conductor may be formed from the grid pattern and each of the separate conductors may have more than two connection pads to be able to interconnect three or more FFC or FPC conductors in two or more FFCs and/or FPCs.

FFC or FPC conductors may be attached to the connection pads via crimping, welding, soldering, or other electrical terminal attachment methods.

Changes in the pattern of the separate conductors can be easily made since the grid pattern would not need to change, only the pattern for severing the separate conductors from the grid pattern which is performed using one of the programmable method detachment methods.

If a second substrate is applied over the grid pattern and first substrate, openings allowing access to the connection pads are cut in the second substrate prior to or after applying the second substrate to the grid pattern.

This method of splicing FFCs and/or FPCs using the splicing device described herein supports increased automation when splicing of multiple FFCs and/or FPCs is required in a cable harness assembly due to its fixed and consistent conductor geometry, and pre-determined attachment method.

Various embodiments of a splicing device that is configured to interconnect flat electrical cables, such as flat flexible cables and/or flexible printed circuits are described herein.

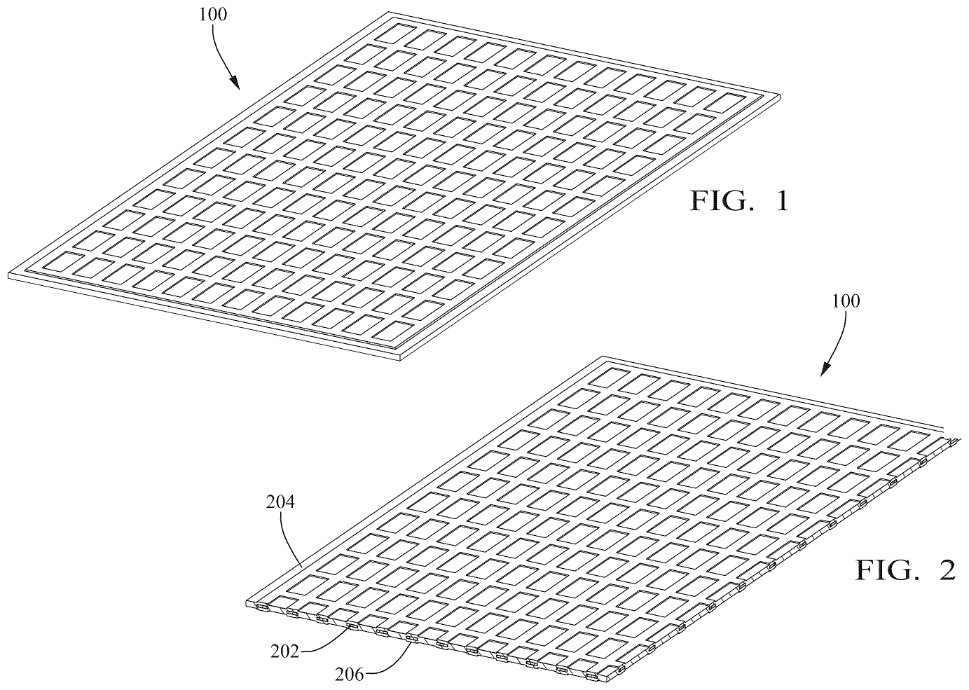

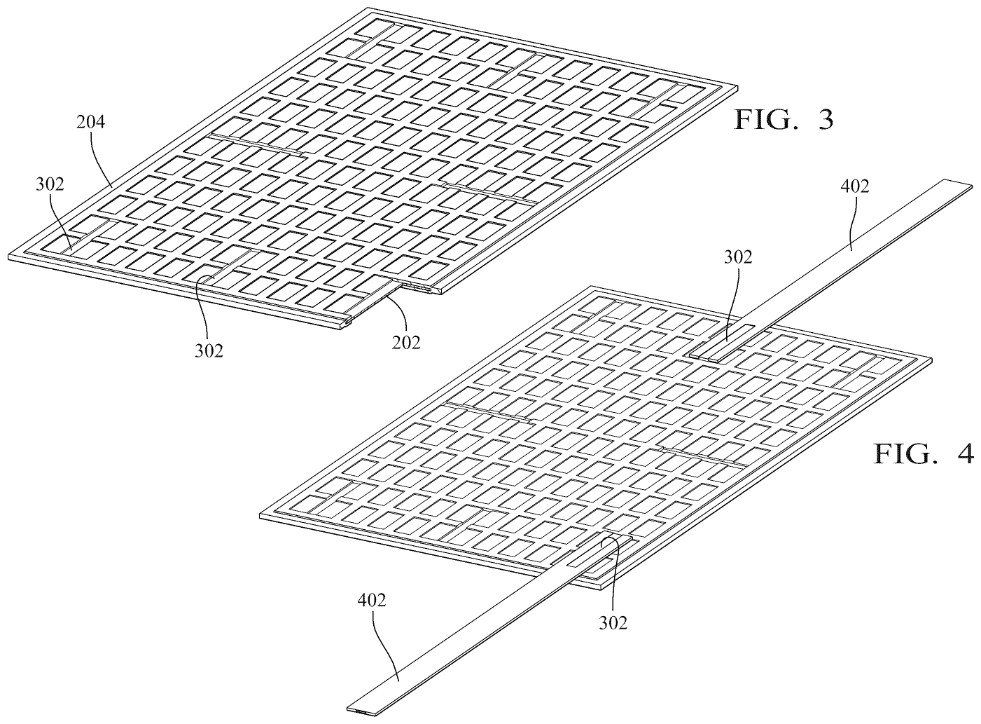

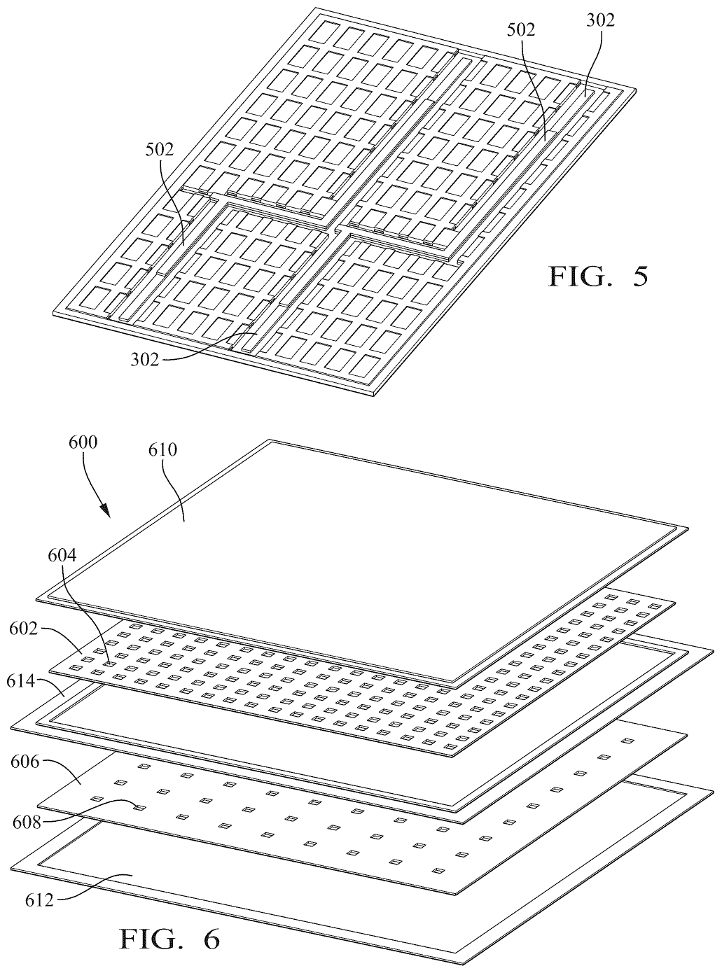

A first embodiment of a splice device 100 is shown in FIGS. 1 to 5. As shown in FIG. 2 the splice device 100 includes an internal grid pattern 202 formed of an electrically conductive material, such as copper or a copper alloy that defines a regularly arranged array of rectangular apertures that form a conductive grid. The grid pattern 202 is contained between two dielectric substrates 204, 206. Besides providing electrical insulation for the grid pattern 202, the substrates 204, 206 may also provide structural rigidity for the splice device 100. As shown in FIG. 3, the top substrate 204 may define openings 302 in the substrate. These openings 302 are configured to allow flat electrical cables 402, such as FFCs and/or FPCs to be attached to the grid pattern 202, e.g., by laser welding, soldering, etc. as shown in FIG. 4. As shown in FIG. 5, separate conductors 502 may be formed in the splice device by severing connections between those separate conductors and the rest of the grid pattern.

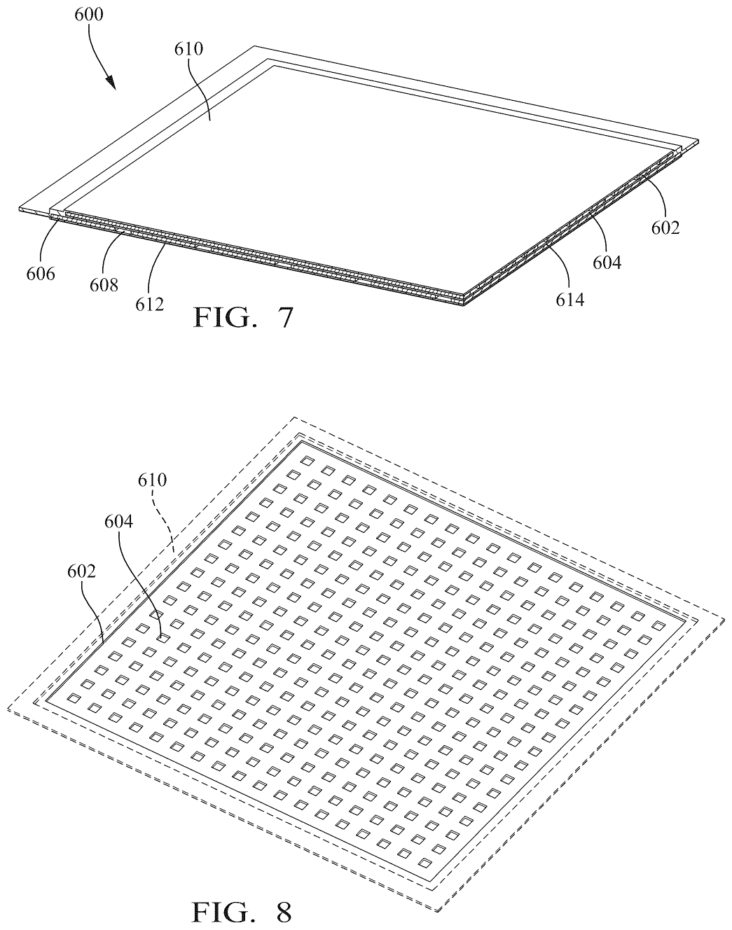

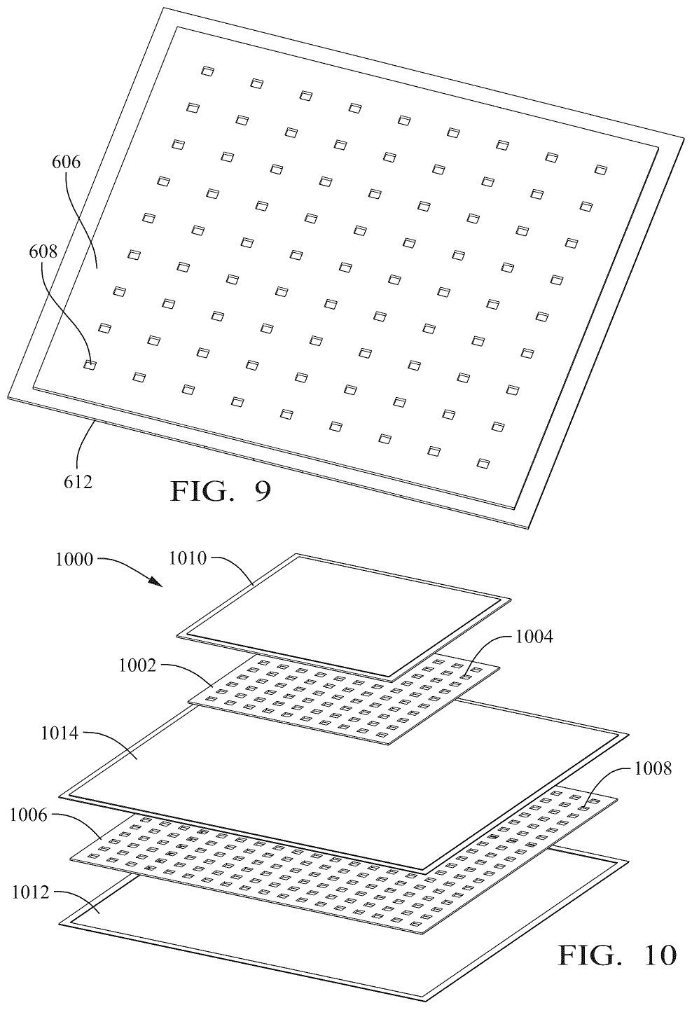

FIGS. 6-9 show a second embodiment of a splice device 600 having a first grid pattern 602 with an array of apertures 604 overlaying and separated from a second grid pattern 606 having an array with fewer apertures 608 than the first grid pattern 602. The first and second grid patterns 602, 606 are covered by outer substrates 610, 612 and separated by an intermediate substrate 614. This arrangement will allow separate conductors formed in the second grid pattern 606 to carry more current than those in the first grid pattern 602 due to their increased width.

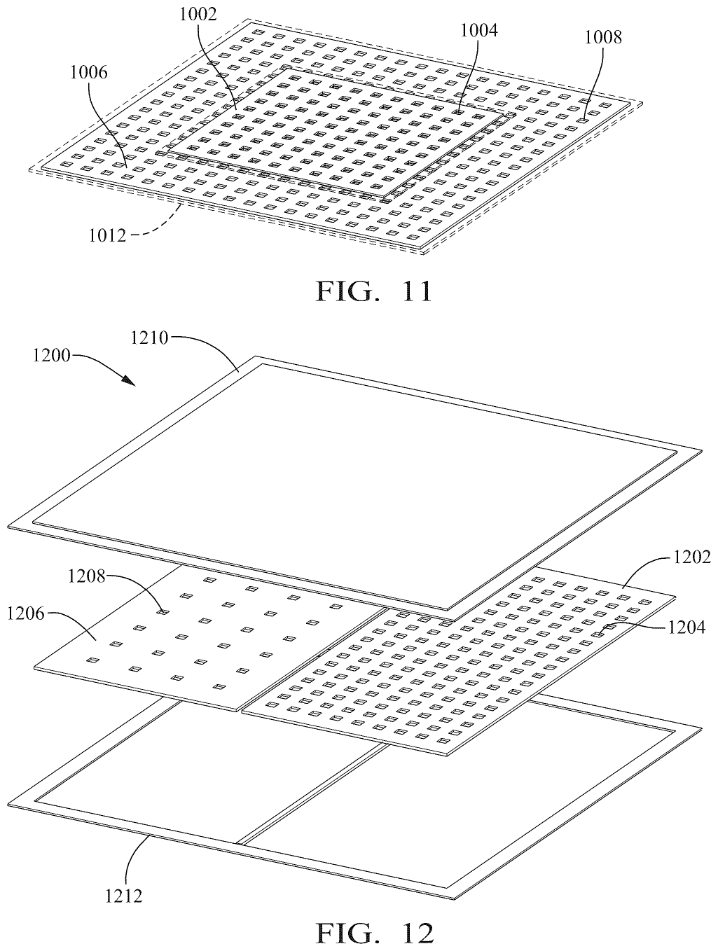

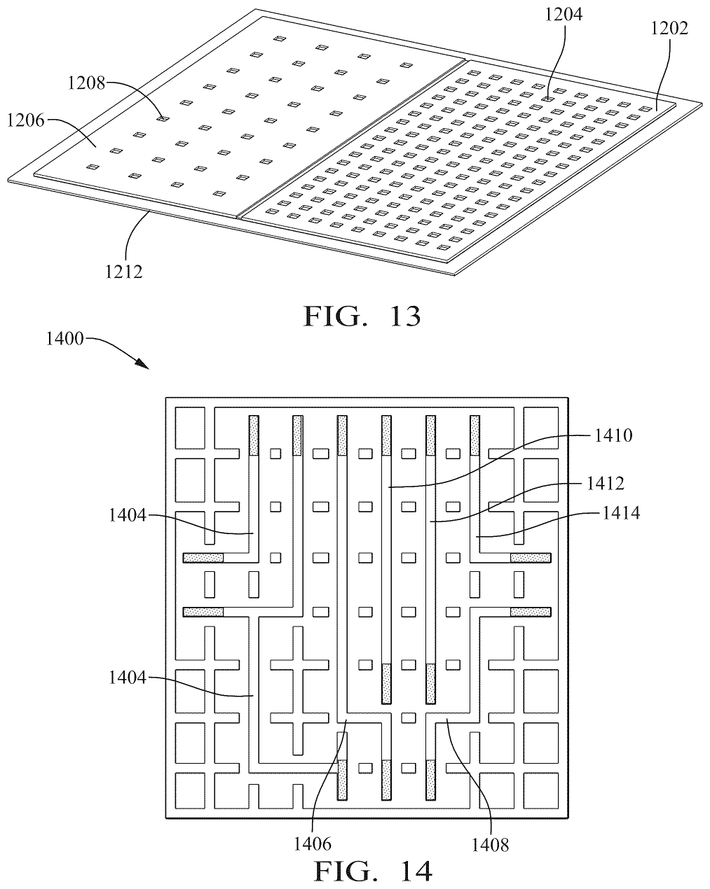

FIGS. 10 and 11 show a third embodiment of a splice device 1000 similar to the splice device 600. Splice device 1000 has a first grid pattern 1006 with an array of apertures 1008 separated from a smaller second grid pattern 1002 with an array of apertures 1004. The first and second grid patterns 1006, 1002 are covered by outer substrates 1010, 1012 and separated by an intermediate substrate 1014.

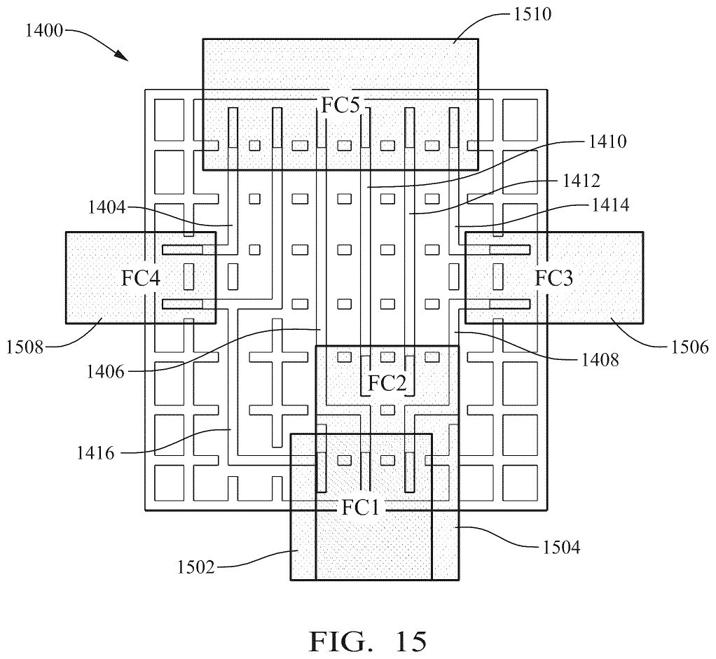

FIGS. 12 and 13 show a fourth embodiment of a splice device 1200 similar to the splice device 600. Splice device 1200 has a first grid pattern 1202 with an array of apertures 1204 arranged adjacent to a second grid pattern 1206 having an array with fewer apertures 1208 than the first grid pattern 1202. The first and second grid patterns 1202, 1206 are covered by outer substrates 1210, 1212. This arrangement will allow separate conductors formed in the second grid pattern 1206 to carry more current than those in the first grid pattern 1202 due to their increased width.

FIG. 14 shows a fifth embodiment of a splice device 1400 with a grid pattern 1402 in which a number of separate conductors 1404, 1406, 1408, 1410, 1412, 1414, 1416 are formed by severing these portions of the grid pattern from the rest of the grid pattern 1402. FIG. 15 shows a number of flat electrical cables 1502, 1504, 1506, 1508, 1510 attached to the separate conductors 1404, 1406, 1408, 1410, 1412, 1416 of grid pattern 1402.

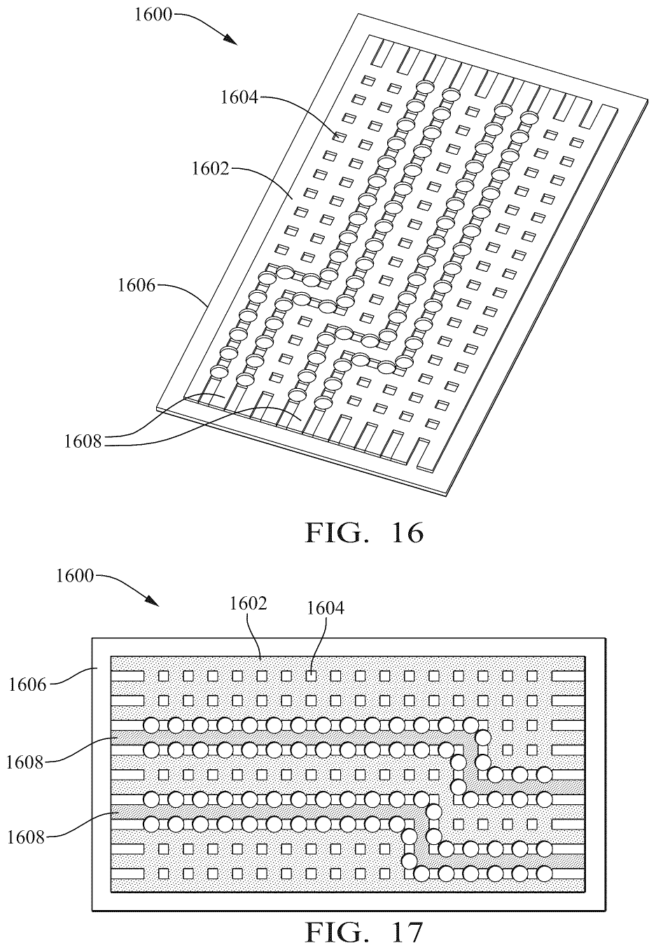

FIGS. 16 and 17 show a sixth embodiment of a splice device 1600 with a grid pattern 1602 defining apertures 1604 and lower substrate 1606 wherein the grid pattern 1602 has been severed to create separate conductors 1608.

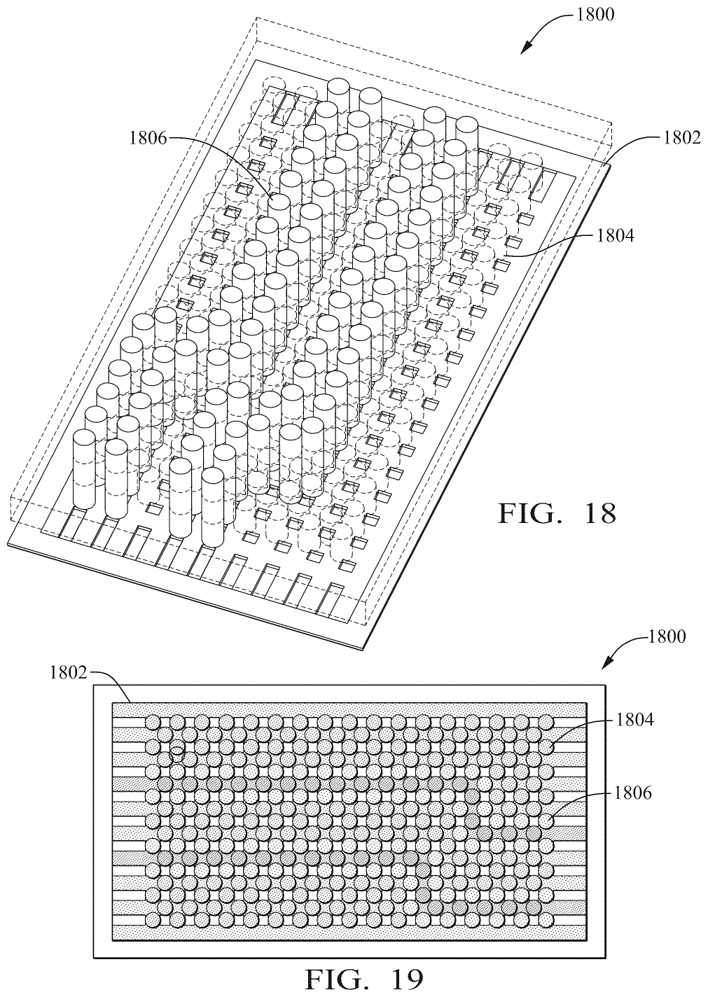

FIGS. 18 and 19 show a punch die 1800 that is configured to sever the separate conductors 1608 from the grid pattern 1602 of the splice device 1600. The punch die 1800 includes a plate 1802 which defines an array of holes 1804 that are arranged to align with the grid pattern 1602 between the apertures 1604. The punch die 1800 also includes a plurality of pins 1806 that are inserted into selected holes 1804 in the plate 1802. As the pins 1806 are pushed through the holes 1804 in the plate 1802, they sever the grid pattern 1602, thereby creating the separate conductors 1608 in the splice device 1600. The plate 1802 may be an upper plate and the punch die 1800 may also include a lower plate (not shown) having holes that align with the holes 1804 to enhance performance of the punch die 1800.

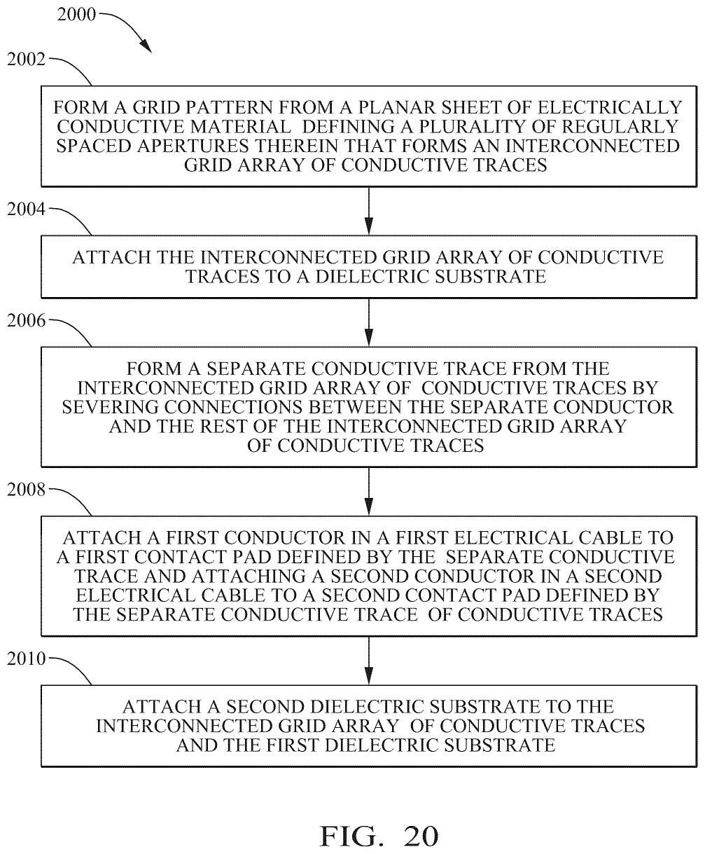

FIG. 20 shows a flowchart of method 2000 of interconnecting flat electrical cables, such as flat flexible cables and/or flexible printed circuits.

In step 2002, a grid pattern is formed from a planar sheet of electrically conductive material defining a plurality of regularly spaced apertures therein that forms an interconnected grid array of conductive traces.

In step 2004, the interconnected grid array of conductive traces is attached to a dielectric substrate.

In step 2006, a separate conductive trace is formed from the interconnected grid array of conductive traces by severing connections between the separate conductor and the rest of the interconnected grid array of conductive traces.

In step 2008, a first conductor in a first electrical cable is attached to a first contact pad defined by the separate conductive trace and a second conductor in a second electrical cable is attached to a second contact pad defined by the separate conductive trace, thereby interconnecting the first conductor to the second conductor via the separate conductive trace.

While the examples presented herein show a rectangular substrate with a regular grid pattern of conductors, alternative embodiments may be envisioned in which the substrate has other geometric shapes as defined by the packaging requirements of the circuit board. Additionally, the width, spacing, and shape of the grid pattern of conductors may also vary from the illustrated examples.

### Discussion of Possible Embodiments

The following are non-exclusive descriptions of possible embodiments of the present invention.

In some aspects, the techniques described herein relate to a method, including: forming a grid pattern from a planar sheet of electrically conductive material defining a plurality of regularly spaced apertures therein that forms an interconnected grid array of conductive traces; attaching the interconnected grid array of conductive traces to a first dielectric substrate; forming a separate conductive trace from the interconnected grid array of conductive traces by severing connections between the separate conductor and the rest of the interconnected grid array of conductive traces; and attaching a first conductor in a first electrical cable to a first contact pad defined by the separate conductive trace and attaching a second conductor in a second electrical cable to a second contact pad defined by the separate conductive trace, thereby interconnecting the first conductor to the second conductor via the separate conductive trace.

The method of the preceding paragraph can optionally include, additionally and/or alternatively any, one or more of the following features/steps, configurations and/or additional components.

In some aspects, the techniques described herein relate to a method, wherein the method further includes attaching a second dielectric substrate to the interconnected grid array of conductive traces and the first dielectric substrate.

In some aspects, the techniques described herein relate to a method, wherein openings are formed in the second dielectric substrate to provide access to the first and second contact pads.

In some aspects, the techniques described herein relate to a method, wherein the openings are formed prior to attaching the second dielectric substrate to the interconnected grid array of conductive traces and the first dielectric substrate.

In some aspects, the techniques described herein relate to a method, wherein the interconnected grid array of conductive traces is attached to the dielectric substrate using a laser welding process.

In some aspects, the techniques described herein relate to a method, wherein the interconnected grid array of conductive traces is attached to the dielectric substrate by a dielectric adhesive.

In some aspects, the techniques described herein relate to a method, wherein the connections between the separate conductor and the rest of the interconnected grid array of conductive traces are severed from the grid pattern by punching out cross connections between the separate conductors and the rest of the grid pattern.

In some aspects, the techniques described herein relate to a method, wherein the connections between the separate conductor and the rest of the interconnected grid array of conductive traces are severed from the grid pattern by a process selected from a list consisting of laser cutting, water jet cutting, blade cutting, and blanking.

In some aspects, the techniques described herein relate to a method, wherein the substrate includes a material selected from a list consisting of polyethylene naphthalate, polyethylene terephthalate, and polyimide.

In some aspects, the techniques described herein relate to a method, wherein the first electrical cable is a flat flexible cable.

In some aspects, the techniques described herein relate to a method, wherein the second electrical cable is a flexible printed circuit.

In some aspects, the techniques described herein relate to a method, wherein each conductive trace in the interconnected grid array of conductive traces has a width between 1.54 mm and 4.08 mm.

In some aspects, the techniques described herein relate to a method, wherein the interconnected grid array of conductive traces has a thickness between 34.8 to 104.8 μm.

In some aspects, the techniques described herein relate to a method, wherein the steps of attaching the first conductor to the first contact pad and attaching the second conductor to the second contact pad are performed using a laser welding process.

In some aspects, the techniques described herein relate to a method, wherein the grid pattern includes a copper or copper alloy material.

In some aspects, the techniques described herein relate to a method, wherein the grid pattern is plated with at least one material selected from a list consisting of tin, tin-based alloys, silver, and gold.

In some aspects, the techniques described herein relate to a splicing device configured to interconnect flat flexible cables (FFC) and/or flexible printed circuits (FPC), the splicing device including: a grid pattern formed from a planar sheet of electrically conductive material having a plurality of regularly spaced apertures therein that forms an interconnected array grid of conductive traces; and a dielectric substrate attached to the interconnected grid array of conductive traces, a separate conductive trace being created from the interconnected grid array of conductive traces by severing connections between the separate conductor and the rest of the interconnected grid array of conductive traces.

The device of the preceding paragraph can optionally include, additionally and/or alternatively any, one or more of the following features/steps, configurations and/or additional components.

In some aspects, the techniques described herein relate to a splicing device, wherein the dielectric substrate is a first dielectric substrate and wherein the splicing device further includes a second dielectric substrate attached to the interconnected grid array of conductive traces and located opposite the first dielectric substrate.

In some aspects, the techniques described herein relate to a splicing device, wherein the second dielectric substrate defines openings that are configured to provide access to first and second contact pads on the separate conductor.

While an exemplary embodiment(s) has been described, it will be understood by those skilled in the art that various changes may be made, and equivalents may be substituted for elements thereof without departing from the scope of the claims. In addition, many modifications may be made to adapt a particular situation or material to the teachings of this disclosure without departing from the essential scope thereof. Therefore, it is intended that the claims are not limited to the disclosed embodiment(s) but include all embodiments falling within the scope of the following claims.

As used herein, ‘one or more’ includes a function being performed by one element, a function being performed by more than one element, e.g., in a distributed fashion, several functions being performed by one element, several functions being performed by several elements, or any combination of the above.

It will also be understood that, although the terms first, second, etc. are, in some instances, used herein to describe various elements, these elements should not be limited by these terms. These terms are only used to distinguish one element from another. For example, a first contact could be termed a second contact, and, similarly, a second contact could be termed a first contact, without departing from the scope of the various described embodiments. The first contact and the second contact are both contacts, but they are not the same contact.

The terminology used in the description of the various described embodiments herein is for the purpose of describing particular embodiments only and is not intended to be limiting. As used in the description of the various described embodiments and the appended claims, the singular forms “a”, “an”, and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

Additionally, while terms of ordinance or orientation may be used herein these elements should not be limited by these terms. All terms of ordinance or orientation, unless stated otherwise, are used for purposes distinguishing one element from another, and do not denote any particular order, order of operations, direction or orientation unless stated otherwise.

1. A method, comprising:
forming a grid pattern from a planar sheet of electrically conductive material defining a plurality of regularly spaced apertures therein that forms an interconnected grid array of conductive traces;
attaching the interconnected grid array of conductive traces to a first dielectric substrate;
forming a separate conductive trace from the interconnected grid array of conductive traces by severing connections between the separate conductive trace and the interconnected grid array of conductive traces; and
attaching a first conductor in a first electrical cable to a first contact pad defined by the separate conductive trace and attaching a second conductor in a second electrical cable to a second contact pad defined by the separate conductive trace, thereby interconnecting the first conductor to the second conductor via the separate conductive trace.

2. The method according to claim 1, wherein the method further includes attaching a second dielectric substrate to the interconnected grid array of conductive traces and the first dielectric substrate.

3. The method according to claim 2, wherein openings are formed in the second dielectric substrate to provide access to the first and second contact pads.

4. The method according to claim 3, wherein the openings are formed prior to attaching the second dielectric substrate to the interconnected grid array of conductive traces and the first dielectric substrate.

5. The method according to claim 1, wherein the interconnected grid array of conductive traces is attached to the dielectric substrate using a laser welding process.

6. The method according to claim 1, wherein the interconnected grid array of conductive traces is attached to the dielectric substrate by a dielectric adhesive.

7. The method according to claim 1, wherein the connections between the separate conductive trace and the interconnected grid array of conductive traces are severed from the grid pattern by punching out cross connections between the separate conductive trace and the interconnected grid array of conductive traces.

8. The method according to claim 1, wherein the connections between the separate conductive trace and the interconnected grid array of conductive traces are severed from the grid pattern by a process selected from a list consisting of laser cutting, water jet cutting, blade cutting, and blanking.

9. The method according to claim 1, wherein the substrate comprises a material selected from a list consisting of polyethylene naphthalate, polyethylene terephthalate, and polyimide.

10. The method according to claim 1, wherein the first electrical cable is a flat flexible cable.

11. The method according to claim 1, wherein the second electrical cable is a flexible printed circuit.

12. The method according to claim 1, wherein each conductive trace in the interconnected grid array of conductive traces has a width between 1.54 mm and 4.08 mm.

13. The method according to claim 1, wherein the interconnected grid array of conductive traces has a thickness between 34.8 to 104.8 μm.

14. The method according to claim 1, wherein the steps of attaching the first conductor to the first contact pad and attaching the second conductor to the second contact pad are performed using a laser welding process.

15. The method according to claim 1, wherein the grid pattern comprises a copper or copper alloy material.

16. The method according to claim 1, wherein the grid pattern is plated with at least one material selected from a list consisting of tin, tin-based alloys, silver, and gold.

17. A splicing device configured to interconnect flat flexible cables (FFC) and/or flexible printed circuits (FPC), the splicing device comprising:
a grid pattern formed from a planar sheet of electrically conductive material having a plurality of regularly spaced apertures therein that forms an interconnected array grid of conductive traces; and
a dielectric substrate attached to the interconnected grid array of conductive traces, a separate conductive trace being created from the interconnected grid array of conductive traces by severing connections between the separate conductive trace and the interconnected grid array of conductive traces.

18. The splicing device according to claim 17, wherein the dielectric substrate is a first dielectric substrate and wherein the splicing device further includes a second dielectric substrate attached to the interconnected grid array of conductive traces and located opposite the first dielectric substrate.

19. The splicing device according to claim 18, wherein the second dielectric substrate defines openings that are configured to provide access to first and second contact pads on the separate conductive trace.
